(19) United States
(12) Patent Application Publication
(10) Pub. No.: US 2015/0318308 A1
(43) Pub. Date: Nov. 5, 2015

(54) LOW TEMPERATURE POLYCRYSTALLINE SILICON BACKPLANE WITH COATED APERTURE EDGES

(71) Applicant: Pixtronix, Inc., San Diego, CA (US)

(72) Inventor: Katsumi Matsumoto, Mobara City (JP)

(73) Assignee: Pixtronix, Inc., San Diego, CA (US)

(21) Appl. No.: 14/266,230

(22) Filed: Apr. 30, 2014

(51) Int. Cl. H01L 27/12; G09G 5/00; G06T 1/60; H01L 27/15; G06T 1/20

(52) U.S. Cl. CPC H01L 27/1222; H01L 27/124; H01L 27/1274; H01L 27/15; G06T 1/20; G06T 1/60; G09G 5/00

(57) ABSTRACT

This disclosure provides systems, methods, and apparatus for forming a display apparatus. In some implementations, a conductive material used for the formation of terminal contacts of a transistor can be also used to form a light absorbing coating over sidewalls of a plurality of apertures formed in an aperture layer of a display apparatus. In some implementations, the conductive material can be patterned such that the display apparatus also includes front facing light absorbing coating over the aperture layer. In some implementations, the front facing light absorbing coating can be electrically connected to a shutter assembly formed over the aperture layer.

### TECHNICAL FIELD

This disclosure relates to the field of displays, and in particular, to the fabrication of transmissive display apparatus.

### DESCRIPTION OF THE RELATED TECHNOLOGY

Electromechanical systems (EMS) devices include devices having electrical and mechanical elements, such as actuators, optical components (such as mirrors, shutters, and/or optical film layers) and electronics. EMS devices can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of deposited material layers, or that add layers to form electrical and electromechanical devices.

EMS-based display apparatus have been proposed that include display elements that modulate light by selectively moving a light blocking component into and out of an optical path through an aperture defined through a light blocking layer. Doing so selectively passes light from a backlight or reflects light from the ambient or a front light to form an image.

### SUMMARY

The systems, methods and devices of the disclosure each have several innovative aspects, no single one of which is solely responsible for the desirable attributes disclosed herein.

One innovative aspect of the subject matter described in this disclosure can be implemented in an apparatus including a transparent substrate, an aperture layer having a plurality of apertures, and a thin film transistor disposed over the aperture layer. For the aperture layer, each of the plurality of apertures have a light absorbing conductive coating covering their respective sidewalls of each of the plurality of apertures. The transistor has a semiconductor channel disposed over the aperture layer, a source metal contact, and a drain metal contact, the source and drain metal contacts being formed concurrently with, and of the same material as, the light absorbing conductive coating formed on the sidewalls of each of the plurality of apertures.

In some implementations, the semiconductor channel includes polycrystalline silicon. In some implementations, the apparatus further includes an additional light absorbing material covering the light absorbing conductive coating formed on the sidewalls and covering the source and drain metal contacts. In some implementations, the apparatus further includes a front facing light absorbing conductive coating over the aperture layer formed concurrently with the light absorbing conductive coating formed on the sidewalls of each of the plurality of apertures. In some implementations, the apparatus further includes a shutter assembly having a shutter supported by an anchor, the anchor electrically connected to the front facing light absorbing conductive coating.

In some implementations, the transistor further includes a gate terminal, the gate terminal disposed between the semiconductor channel and the aperture layer. In some implementations, the transistor further includes a gate terminal, the semiconductor channel being disposed between the gate terminal and the aperture layer.

In some implementations, the apparatus further includes a display including the substrate, the aperture layer and the transistor, a processor that is capable of communicating with the display, the processor being capable of processing image data; and a memory device that is capable of communicating with the processor. In some such implementations, the display further includes a driver circuit capable of sending at least one signal to the display, and a controller capable of sending at least a portion of the image data to the driver circuit. In some implementations, the apparatus further includes an image source module capable of sending the image data to the processor, where the image source module includes at least one of a receiver, transceiver, and transmitter. In some implementations, the display device further includes an input device capable of receiving input data and to communicate the input data to the processor.

Another innovative aspect of the subject matter described in this disclosure can be implemented in a method for forming a display apparatus. The method includes forming a plurality of openings in a reflective layer deposited on a transparent substrate, forming a semiconductor channel of a thin film transistor over the reflective layer, and depositing and patterning a light absorbing conductive layer to form source and drain contacts of the transistor and to concurrently form light absorbing coatings covering sidewalls of each of the plurality of openings.

In some implementations, the method further includes depositing and patterning an additional light absorbing material to cover the source and drain contacts and to cover the light absorbing coatings covering the sidewalls of each of the plurality of openings. In some implementations, forming the semiconductor channel of the transistor over the reflective layer includes converting an amorphous silicon material deposited over the aperture layer into polycrystalline silicon by an annealing process. In some implementations, the method further includes forming a gate terminal of the transistor prior to forming the semiconductor channel of the transistor over the reflective layer.

In some implementations, the method further includes forming a gate terminal of the transistor after forming the semiconductor channel of the transistor over the reflective layer. In some implementations, depositing and patterning the light absorbing conductive layer to form source and drain contacts of the transistor and to concurrently form light absorbing coatings covering the sidewalls of each of the plurality of openings further includes patterning a front facing light absorbing conductive coating over the aperture layer. In some implementations, the method further includes forming a shutter assembly over the aperture layer such that at least a portion of the shutter assembly is in electrical contact with the front facing light absorbing conductive coating.

Details of one or more implementations of the subject matter described in this specification are set forth in the accompanying drawings and the description below. Although the examples provided in this summary are primarily described in terms of MEMS-based displays, the concepts provided herein may apply to other types of displays, such as liquid crystal displays (LCD), organic light emitting diode (OLED) displays, electrophoretic displays, and field emission displays, as well as to other non-display MEMS devices, such as MEMS microphones, sensors, and optical switches. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1A shows an example schematic diagram of a direct-view microelectromechanical systems (MEMS) based display apparatus.

FIG. 1B shows an example block diagram of a host device.

FIGS. 2A and 2B show views of an example dual actuator shutter assembly.

FIG. 3 shows an example cross-sectional view of a portion of a display apparatus.

FIGS. 4A-4J show cross-sectional views of the display apparatus 300 shown in FIG. 3, at various example stages of construction.

FIG. 5 shows a flow diagram of an example process 500 for forming a display apparatus.

FIGS. 6A and 6B show system block diagrams illustrating a display device that includes a plurality of display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (such as e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

In some implementations, a conductive material used for the formation of terminal contacts of a transistor can be also used to form a light absorbing coating over sidewalls of a plurality of apertures formed in an aperture layer of a display apparatus. In some implementations, the conductive material also can be patterned such that the display apparatus also includes a front facing light absorbing coating over the aperture layer. In some implementations, the front facing light absorbing coating can be electrically connected to a shutter assembly formed over the aperture layer.

Particular implementations of the subject matter described in this disclosure can be implemented to realize one or more of the following potential advantages. By forming a light absorbing coating on sidewalls of apertures in an aperture layer in a display apparatus, incident light that would otherwise reflect towards a viewer is absorbed by the light absorbing coating. By reducing the reflection of light off of the sidewalls of the aperture, the contrast ratio of the display apparatus can be improved. In some implementations, by forming the light absorbing coating on the sidewalls of the apertures concurrently with, and using the same material as, terminal contacts of a transistor, the number of processing stages used for forming the display apparatus can be reduced. The use of terminal contact materials as a light absorbing material can be particularly advantageous in fabrication processes that involve the use of high temperature processing, such as the laser annealing process used in the formation of the active layers of low-temperature polycrystalline silicon (LTPS) thin film transistors (TFTs), for which light absorbing resins or other light absorbing materials may not be compatible.

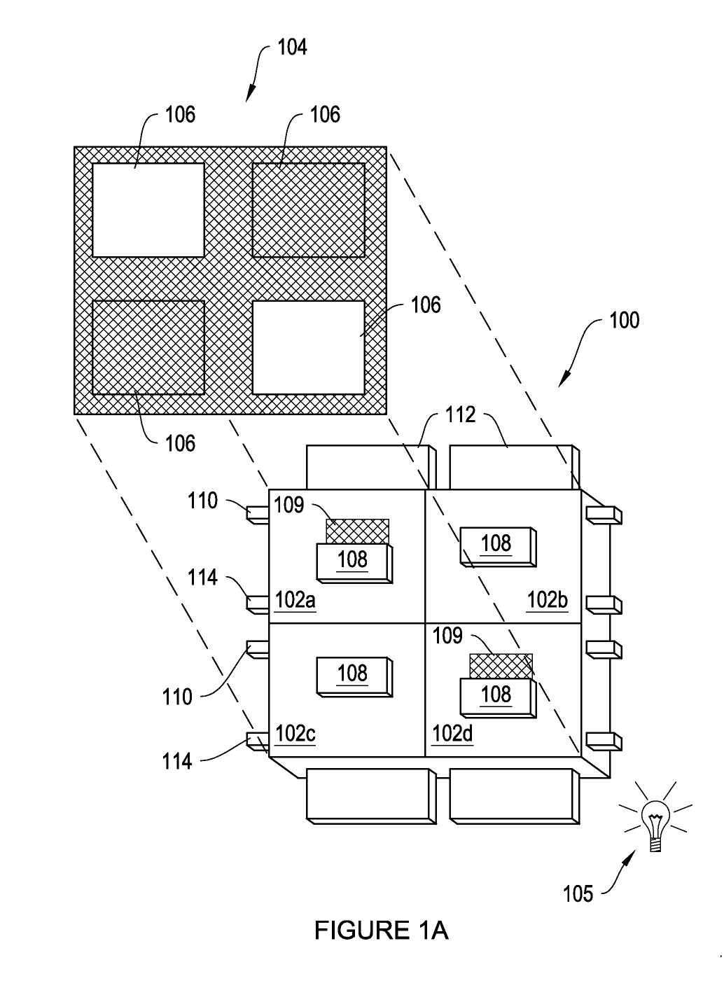

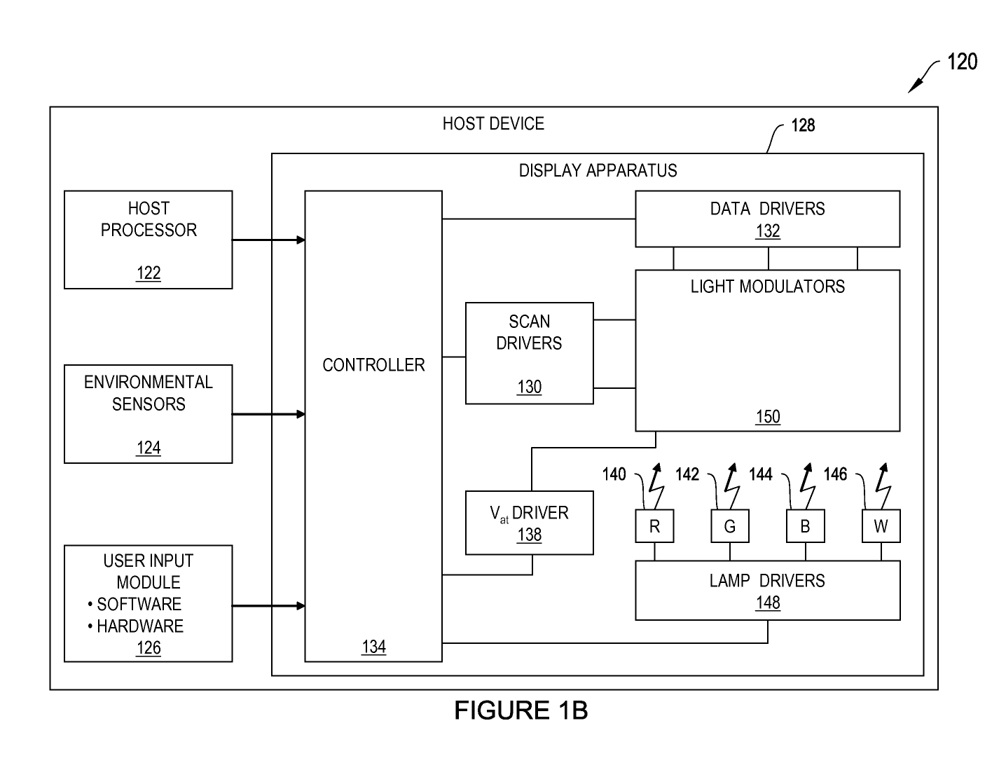

FIG. 1A shows a schematic diagram of an example direct-view MEMS-based display apparatus 100. The display apparatus 100 includes a plurality of light modulators 102a-102d (generally light modulators 102) arranged in rows and columns. In the display apparatus 100, the light modulators 102a and 102d are in the open state, allowing light to pass. The light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps positioned in the front of the display, i.e., by use of a front light.

In some implementations, each light modulator 102 corresponds to a pixel 106 in the image 104. In some other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide a luminance level in an image 104. With respect to an image, a pixel corresponds to the smallest picture element defined by the resolution of image. With respect to structural components of the display apparatus 100, the term pixel refers to the combined mechanical and electrical components utilized to modulate the light that forms a single pixel of the image.

The display apparatus 100 is a direct-view display in that it may not include imaging optics typically found in projection applications. In a projection display, the image formed on the surface of the display apparatus is projected onto a screen or onto a wall. The display apparatus is substantially smaller than the projected image. In a direct view display, the user sees the image by looking directly at the display apparatus, which contains the light modulators and optionally a backlight or front light for enhancing brightness and/or contrast seen on the display.

Direct-view displays may operate in either a transmissive or reflective mode. In a transmissive display, the light modulators filter or selectively block light which originates from a lamp or lamps positioned behind the display. The light from the lamps is optionally injected into a lightguide or backlight so that each pixel can be uniformly illuminated. Transmissive direct-view displays are often built onto transparent or glass substrates to facilitate a sandwich assembly arrangement where one substrate, containing the light modulators, is positioned over the backlight.

Each light modulator 102 can include a shutter 108 and an aperture 109. To illuminate a pixel 106 in the image 104, the shutter 108 is positioned such that it allows light to pass through the aperture 109 towards a viewer. To keep a pixel 106 unlit, the shutter 108 is positioned such that it obstructs the passage of light through the aperture 109. The aperture 109 is defined by an opening patterned through a reflective or light-absorbing material in each light modulator 102.

The display apparatus also includes a control matrix connected to the substrate and to the light modulators for controlling the movement of the shutters. The control matrix includes a series of electrical interconnects (such as interconnects 110, 112 and 114), including at least one write-enable interconnect 110 (also referred to as a scan-line interconnect) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the write-enabling voltage, V_{WE}), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In some other implementations, the data voltage pulses control switches, such as transistors or other non-linear circuit elements that control the application of separate actuation voltages, which are typically higher in magnitude than the data voltages, to the light modulators 102. The application of these actuation voltages then results in the electrostatic driven movement of the shutters 108.

FIG. 1B shows a block diagram of an example host device 120 (i.e., cell phone, smart phone, PDA, MP3 player, tablet, e-reader, netbook, notebook, watch, etc.). The host device 120 includes a display apparatus 128, a host processor 122, environmental sensors 124, a user input module 126, and a power source.

The display apparatus 128 includes a plurality of scan drivers 130 (also referred to as write enabling voltage sources), a plurality of data drivers 132 (also referred to as data voltage sources), a controller 134, common drivers 138, lamps 140-146, lamp drivers 148 and an array 150 of display elements, such as the light modulators 102 shown in FIG. 1A. The scan drivers 130 apply write enabling voltages to scan-line interconnects 110. The data drivers 132 apply data voltages to the data interconnects 112.

In some implementations of the display apparatus, the data drivers 132 are configured to provide analog data voltages to the array 150 of display elements, especially where the luminance level of the image 104 is to be derived in analog fashion. In analog operation, the light modulators 102 are designed such that when a range of intermediate voltages is applied through the data interconnects 112, there results a range of intermediate open states in the shutters 108 and therefore a range of intermediate illumination states or luminance levels in the image 104. In other cases, the data drivers 132 are configured to apply only a reduced set of 2, 3 or 4 digital voltage levels to the data interconnects 112. These voltage levels are designed to set, in digital fashion, an open state, a closed state, or other discrete state to each of the shutters 108.

The scan drivers 130 and the data drivers 132 are connected to a digital controller circuit 134 (also referred to as the controller 134). The controller sends data to the data drivers 132 in a mostly serial fashion, organized in sequences, which may be predetermined, grouped by rows and by image frames. The data drivers 132 can include series to parallel data converters, level shifting, and for some applications digital to analog voltage converters.

The display apparatus optionally includes a set of common drivers 138, also referred to as common voltage sources. In some implementations, the common drivers 138 provide a DC common potential to all display elements within the array 150 of display elements, for instance by supplying voltage to a series of common interconnects 114. In some other implementations, the common drivers 138, following commands from the controller 134, issue voltage pulses or signals to the array 150 of display elements, for instance global actuation pulses which are capable of driving and/or initiating simultaneous actuation of all display elements in multiple rows and columns of the array 150.

All of the drivers (such as scan drivers 130, data drivers 132 and common drivers 138) for different display functions are time-synchronized by the controller 134. Timing commands from the controller coordinate the illumination of red, green, blue and white lamps (140, 142, 144 and 146 respectively) via lamp drivers 148, the write-enabling and sequencing of specific rows within the array 150 of display elements, the output of voltages from the data drivers 132, and the output of voltages that provide for display element actuation. In some implementations, the lamps are light emitting diodes (LEDs).

The controller 134 determines the sequencing or addressing scheme by which each of the shutters 108 can be re-set to the illumination levels appropriate to a new image 104. New images 104 can be set at periodic intervals. For instance, for video displays, the color images 104 or frames of video are refreshed at frequencies ranging from 10 to 300 Hertz (Hz). In some implementations the setting of an image frame to the array 150 is synchronized with the illumination of the lamps 140, 142, 144 and 146 such that alternate image frames are illuminated with an alternating series of colors, such as red, green, blue and white. The image frames for each respective color are referred to as color subframes. In this method, referred to as the field sequential color method, if the color subframes are alternated at frequencies in excess of 20 Hz, the human brain will average the alternating frame images into the perception of an image having a broad and continuous range of colors. In alternate implementations, four or more lamps with primary colors can be employed in display apparatus 100, employing primaries other than red, green, blue and white.

In some implementations, where the display apparatus 100 is designed for the digital switching of shutters 108 between open and closed states, the controller 134 forms an image by the method of time division grayscale, as previously described. In some other implementations, the display apparatus 100 can provide grayscale through the use of multiple shutters 108 per pixel.

In some implementations, the data for an image 104 state is loaded by the controller 134 to the display element array 150 by a sequential addressing of individual rows, also referred to as scan lines. For each row or scan line in the sequence, the scan driver 130 applies a write-enable voltage to the write enable interconnect 110 for that row of the array 150, and subsequently the data driver 132 supplies data voltages, corresponding to desired shutter states, for each column in the selected row. This process repeats until data has been loaded for all rows in the array 150. In some implementations, the sequence of selected rows for data loading is linear, proceeding from top to bottom in the array 150. In some other implementations, the sequence of selected rows is pseudo-randomized, in order to minimize visual artifacts. And in some other implementations, the sequencing is organized by blocks, where, for a block, the data for only a certain fraction of the image 104 state is loaded to the array 150, for instance by addressing only every 5^{th} row of the array 150 in sequence.

In some implementations, the process for loading image data to the array 150 is separated in time from the process of actuating the display elements in the array 150. In these implementations, the display element array 150 may include data memory elements for each display element in the array 150 and the control matrix may include a global actuation interconnect for carrying trigger signals, from common driver 138, to initiate simultaneous actuation of shutters 108 according to data stored in the memory elements.

In alternative implementations, the array 150 of display elements and the control matrix that controls the display elements may be arranged in configurations other than rectangular rows and columns. For example, the display elements can be arranged in hexagonal arrays or curvilinear rows and columns. In general, as used herein, the term scan-line shall refer to any plurality of display elements that share a write-enabling interconnect.

The host processor 122 generally controls the operations of the host. For example, the host processor 122 may be a general or special purpose processor for controlling a portable electronic device. With respect to the display apparatus 128, included within the host device 120, the host processor 122 outputs image data as well as additional data about the host. Such information may include data from environmental sensors, such as ambient light or temperature; information about the host, including, for example, an operating mode of the host or the amount of power remaining in the host's power source; information about the content of the image data; information about the type of image data; and/or instructions for display apparatus for use in selecting an imaging mode.

The user input module 126 conveys the personal preferences of the user to the controller 134, either directly, or via the host processor 122. In some implementations, the user input module 126 is controlled by software in which the user programs personal preferences such as deeper color, better contrast, lower power, increased brightness, sports, live action, or animation. In some other implementations, these preferences are input to the host using hardware, such as a switch or dial. The plurality of data inputs to the controller 134 direct the controller to provide data to the various drivers 130, 132, 138 and 148 which correspond to optimal imaging characteristics.

An environmental sensor module 124 also can be included as part of the host device 120. The environmental sensor module 124 receives data about the ambient environment, such as temperature and or ambient lighting conditions. The sensor module 124 can be programmed to distinguish whether the device is operating in an indoor or office environment versus an outdoor environment in bright daylight versus an outdoor environment at nighttime. The sensor module 124 communicates this information to the display controller 134, so that the controller 134 can optimize the viewing conditions in response to the ambient environment.

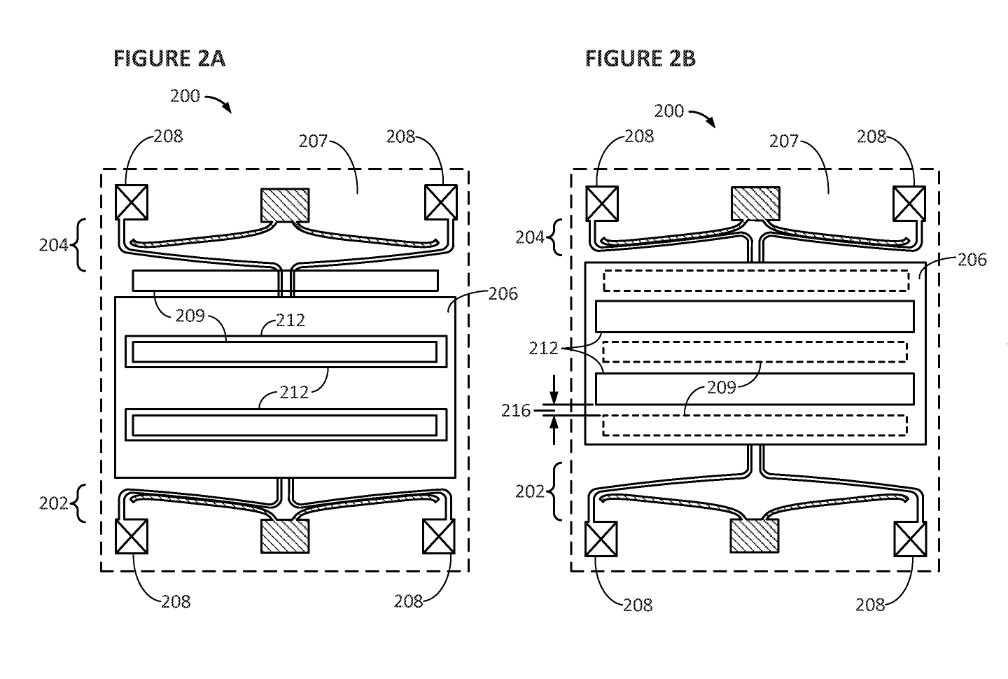

FIGS. 2A and 2B show views of an example dual actuator shutter assembly 200. The dual actuator shutter assembly 200, as depicted in FIG. 2A, is in an open state. FIG. 2B shows the dual actuator shutter assembly 200 in a closed state. The shutter assembly 200 includes actuators 202 and 204 on either side of a shutter 206. Each actuator 202 and 204 is independently controlled. A first actuator, a shutter-open actuator 202, serves to open the shutter 206. A second opposing actuator, the shutter-close actuator 204, serves to close the shutter 206. Both of the actuators 202 and 204 are compliant beam electrode actuators. The actuators 202 and 204 open and close the shutter 206 by driving the shutter 206 substantially in a plane parallel to an aperture layer 207 over which the shutter is suspended. The shutter 206 is suspended a short distance over the aperture layer 207 by anchors 208 attached to the actuators 202 and 204. The inclusion of supports attached to both ends of the shutter 206 along its axis of movement reduces out of plane motion of the shutter 206 and confines the motion substantially to a plane parallel to the substrate.

The shutter 206 includes two shutter apertures 212 through which light can pass. The aperture layer 207 includes a set of three apertures 209. In FIG. 2A, the shutter assembly 200 is in the open state and, as such, the shutter-open actuator 202 has been actuated, the shutter-close actuator 204 is in its relaxed position, and the centerlines of the shutter apertures 212 coincide with the centerlines of two of the aperture layer apertures 209. In FIG. 2B the shutter assembly 200 has been moved to the closed state and, as such, the shutter-open actuator 202 is in its relaxed position, the shutter-close actuator 204 has been actuated, and the light blocking portions of the shutter 206 are now in position to block transmission of light through the apertures 209 (depicted as dotted lines).

Each aperture has at least one edge around its periphery. For example, the rectangular apertures 209 have four edges. In alternative implementations in which circular, elliptical, oval, or other curved apertures are formed in the aperture layer 207, each aperture may have only a single edge. In some other implementations, the apertures need not be separated or disjoint in the mathematical sense, but instead can be connected. That is to say, while portions or shaped sections of the aperture may maintain a correspondence to each shutter, several of these sections may be connected such that a single continuous perimeter of the aperture is shared by multiple shutters.

In order to allow light with a variety of exit angles to pass through apertures 212 and 209 in the open state, it is advantageous to provide a width or size for shutter apertures 212 which is larger than a corresponding width or size of apertures 209 in the aperture layer 207. In order to effectively block light from escaping in the closed state, it is preferable that the light blocking portions of the shutter 206 overlap the apertures 209. FIG. 2B shows an overlap 216, which in some implementations can be predefined, between the edge of light blocking portions in the shutter 206 and one edge of the aperture 209 formed in the aperture layer 207.

The electrostatic actuators 202 and 204 are designed so that their voltage-displacement behavior provides a bi-stable characteristic to the shutter assembly 200. For each of the shutter-open and shutter-close actuators there exists a range of voltages below the actuation voltage, which if applied while that actuator is in the closed state (with the shutter being either open or closed), will hold the actuator closed and the shutter in position, even after an actuation voltage is applied to the opposing actuator. The minimum voltage needed to maintain a shutter's position against such an opposing force is referred to as a maintenance voltage Vₘ.

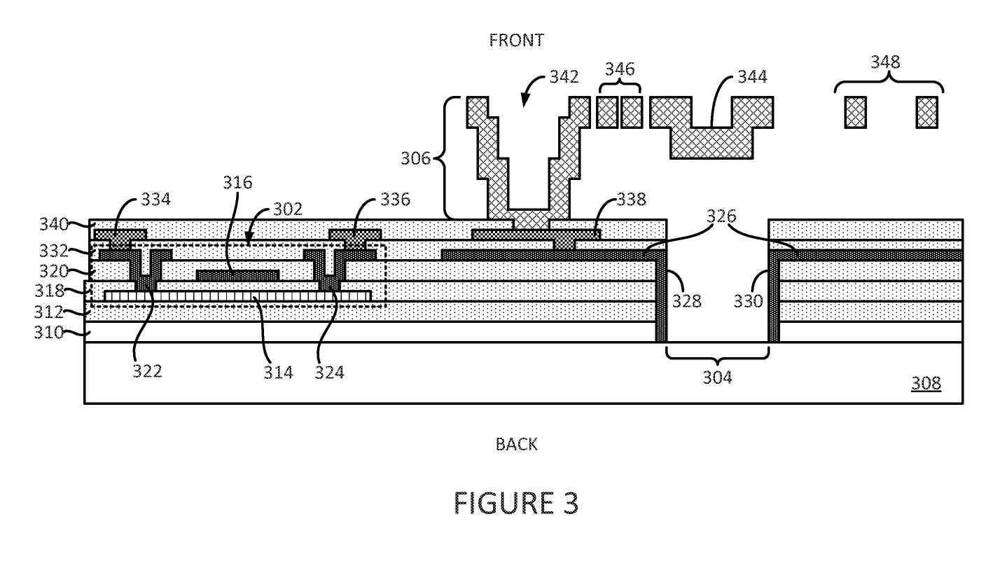

FIG. 3 shows an example cross-sectional view of a portion of a display apparatus 300. In particular, the cross-sectional view shows a LTPS TFT 302, an aperture 304 and a shutter assembly 306 for modulating light passing through the aperture 304. During the manufacture of the display apparatus 300, the LTPS TFT 302 and the aperture 304 are formed such that a conducting layer used for forming drain and source terminals of the LTPS TFT 302 is also used for forming a light absorbing coating on the sidewalls of the aperture 300.

As shown in FIG. 3, the display apparatus 300 includes a transparent substrate 308. In some implementations, the transparent substrate 308 can be made of materials such as plastic, polymer, quartz or glass. While not shown in FIG. 3, a light source such as a backlight can be positioned behind the substrate 308, with respect to the shutter assembly 306.

The aperture 304 is defined by an opening in an aperture layer 310 deposited over the substrate 308. The aperture layer 310 can be patterned to form several apertures similar to the aperture 304. In some implementations, the aperture layer 310 can be, or include, a rear facing reflective film. The reflective film can reflect light emitted by the light source and not passing through the aperture 304 back towards the rear of the display apparatus 300. The rear of the display apparatus 300 can include a front facing mirror (not shown) which can re-direct light reflected by the reflective film back towards the front of the display apparatus, thereby improving overall light output of the display apparatus 300.

In some implementations, the display apparatus 300 can also include a first insulation layer 312 for insulating the aperture layer 310 from the LTPS TFT 302. In some other implementation, the LTPS TFT 302 can be directly formed over the aperture layer 310.

In some implementations, after the formation of the aperture layer 310, a light absorbing layer could be deposited over the aperture layer 310. The light absorbing layer can be patterned to form a light absorbing coating over the sidewalls of the aperture 304. Coating the sides of the aperture 304 can reduce undesirable side reflections and refractions of light passing through the aperture 304. Reducing the undesirable reflections and refractions can, in turn, improve the contrast ratio of the display apparatus 300.

In some implementations (not shown in FIG. 3), the light absorbing layer may include photosensitive resins that are sensitive to UV light. Having a photosensitive light absorbing layer can allow patterning of one or more layer of the display apparatus 300 without the need of a separate resist layer being applied.

However, polymer-based light absorbing layers may not be compatible with the manufacturing processes used in fabricating display apparatus including LTPS TFTs, such as display apparatus 300. In particular, the formation of a semiconductor channel of the LTPS TFT 302 may irreparably damage the underlying light absorbing layer as well as adjacent layers of material. For example, in some implementations, the polycrystalline silicon channel of the LTPS TFT 302 can be formed by first depositing an amorphous silicon layer, and then using an excimer laser annealing process to convert the amorphous silicon layer into polycrystalline silicon. The converted polycrystalline silicon layer can then be patterned to form a channel of the LTPS TFT 302. In some implementations, the laser annealing process results in high temperatures over 250 degrees Celsius, which can damage the underlying light absorbing layer, which, in turn, also can result in damage to adjacent structures in the display apparatus 300. In some implementations, the polymer or resin-based light absorbing layer may deform, combust, or generally react to the annealing process in a manner that may damage adjacent structures in the display apparatus 300. In some implementations, this could cause significant amount of stress build-up in the amorphous silicon layer as it crystalizes into polycrystalline silicon.

Accordingly, instead of including a polymer or resin-based light absorbing layer, the display apparatus 300 includes a light absorbing mask patterned out of material in the metal layer used for forming the drain and source terminals of the LTPS TFT 302. In some implementations, for example, the light absorbing mask is also used to form coatings over the sidewalls of the aperture 304.

As shown in FIG. 3, the LTPS TFT 302 is formed over the first insulation layer 312. The polycrystalline silicon channel 314 is formed over the first insulation layer 312 by the laser annealing process mentioned above. The LTPS TFT 302 also includes a gate terminal 316 separated from the channel 314 by a second insulation layer 318. The second insulation layer 318 and a third insulation layer 320 are patterned to allow the formation of source and drain terminals 322 and 324. The source and drain terminals 322 and 324 make contact with the channel 314. The conducting material used to form the source and drain terminals 322 and 324 is also used to form the light absorbing mask discussed above. The light absorbing mask includes a front facing light absorbing portion 326 and sidewall coating portions 328 and 330 on the sidewalls of the aperture 304. The front facing light absorbing portion 326 can absorb light incident on its front facing surface from the front of the display apparatus 300 or reflecting off of the rear-facing surfaces of the shutter assembly 306. The sidewall coating portions 328 and 330 absorb light impinging on the sidewalls of the aperture 304 that would otherwise reflect or refract off the sidewalls as it passes through the aperture 304. The absorption of light by the front facing light absorbing portion 326 and the sidewall coating portions 328 and 330 of the light absorbing mask can improve the contrast ratio of the display apparatus 300.

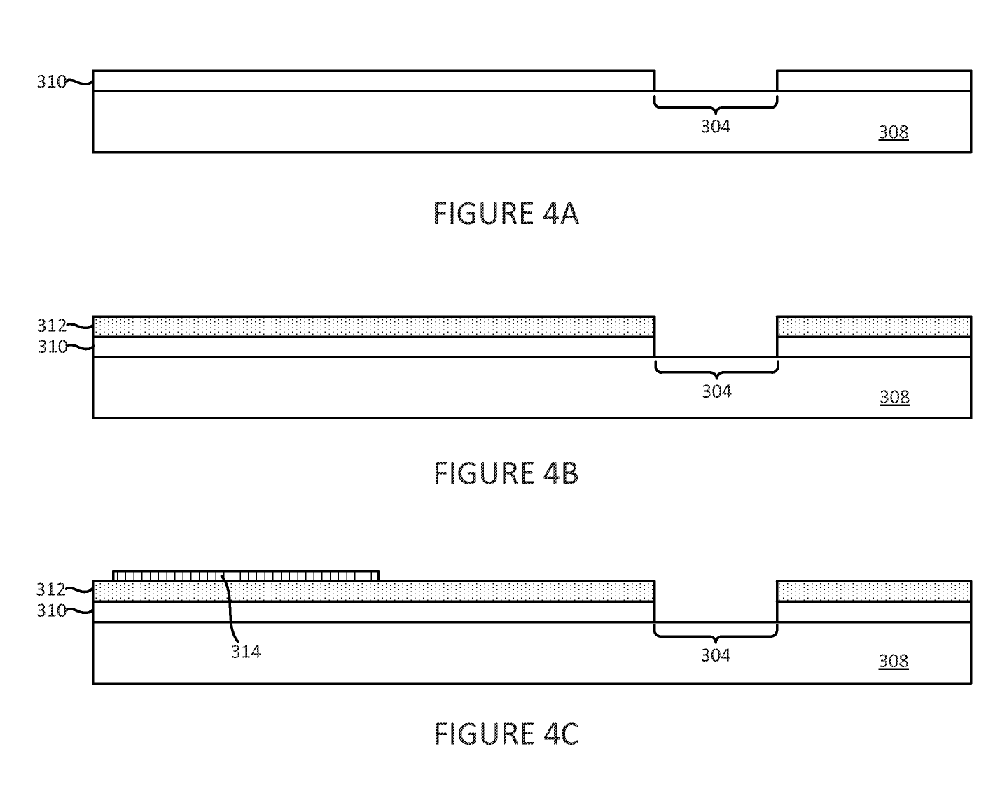

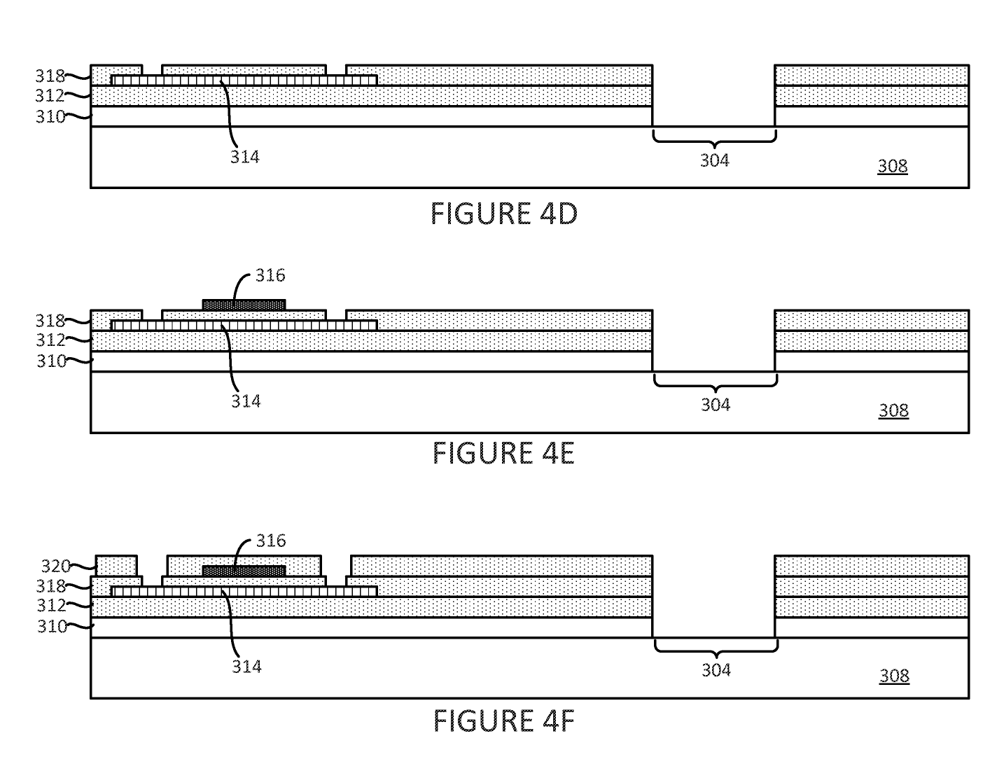

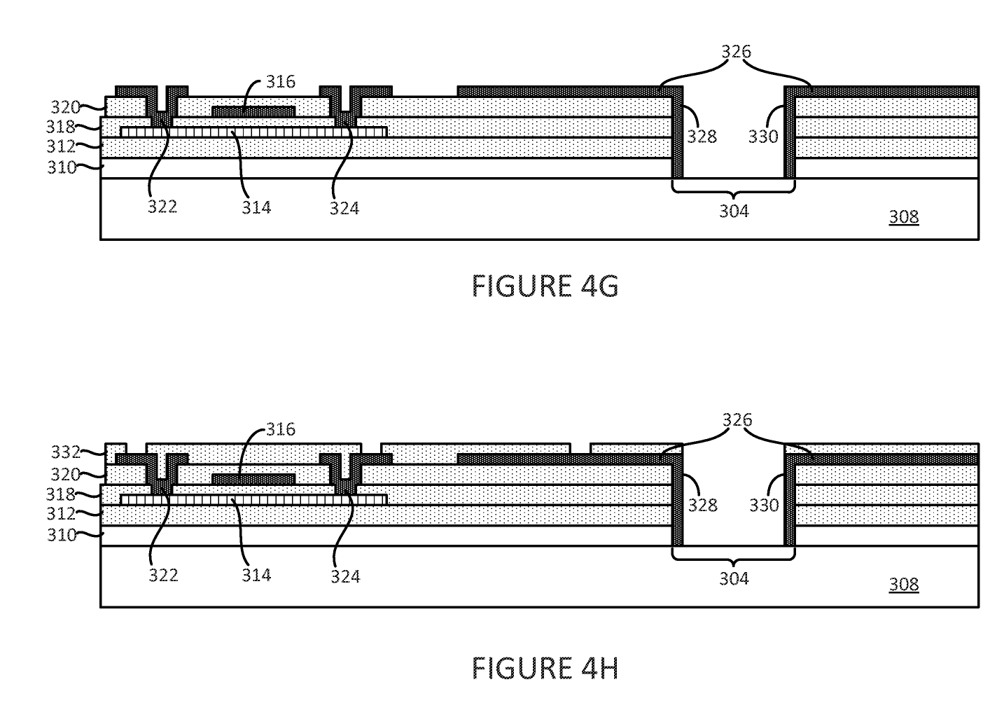

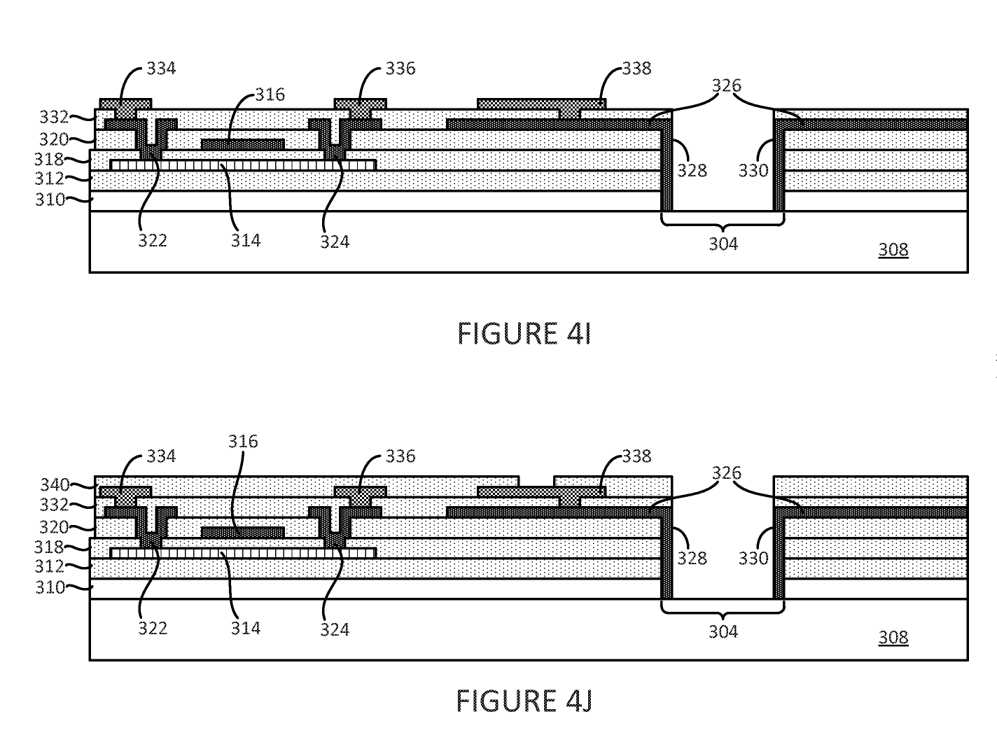

It should be noted that the front facing light absorbing portion 326 and the sidewall coating portions 328 and 330 of the light absorbing mask are patterned from the same conducting material used to form the source and drain terminals 322 and 324 of the LTPS TFT 302. Thus, as described further in relation to FIGS. 4A-4J, the deposition and patterning stages employed to form the source and drain terminals 322 and 324 of the LTPS TFT 302 can also be used to pattern and form the front facing light absorbing portion 326 and the sidewall coating portions 328 and 330 of the light absorbing mask. Thus, the formation of the light absorbing mask does not result in additional dedicated deposition and patterning stages—resulting in a reduction in the time and costs associated with the manufacture of the display apparatus 300.

The display apparatus 300 further includes a fourth insulation layer 332 for insulating the source and drain terminals 322 and 324 and the front facing light absorbing portion 326 of the light absorbing mask. The fourth insulation layer 332 includes openings that allow vias formed from later deposited conductor layers to make contact with the source and drain terminals 322 and 324 and with the front facing light absorbing portion 326 of the light absorbing mask. For example, a first via 334 makes contact with the source terminal 322, a second via 336 makes contact with the drain terminal 324 and a third via 338 makes contact with a the front facing light absorbing portion 326 near the shutter assembly 306.

The display apparatus 300 can also include a fifth insulation layer 340 for insulating the first, second and third vias 334, 336 and 338. In some implementations, the fifth insulation layer 338 can include openings to allow an anchor 342 of the shutter assembly 306 to make electrical contact with the front facing light absorbing coating 326 through the third via 338. In some implementations, the electrical contact between the shutter assembly 306 and the front facing light absorbing portion 326 of the light absorbing mask can aid in reducing or removing voltage differences between the shutter assembly 306 and any one of the layers deposited over the substrate 308. Reducing or removing the voltage differences can, in turn, mitigate undesirable electrostatic forces that may pull on various portions of the shutter assembly 306.

The shutter assembly 306 can be disposed over the fifth insulation layer 340. The shutter assembly 306 can include an anchor 342, a shutter 344, a first set of actuator beams 346 and a second set of actuator beams 348. The shutter assembly 306 can be supported over the aperture 304 by the anchor 342. The first set of actuator beams 346 and the second set of actuator beams 348 can be appropriately actuated to position the shutter 344 at a desired location over the aperture 304. For example, as shown in FIG. 3, the first set of actuators 346 are actuated to position the shutter 344 over the aperture 304 such that light passing through the aperture 304 is blocked by the shutter 344 from reaching the front of the display apparatus 300. That is, the shutter 344 is in the CLOSED position. In some implementations, the second set of actuators 348 can be actuated to pull the shutter 344 (in a plane parallel to the top surface of the fifth insulation layer 340) away from the aperture 304 such that light emerging from the aperture 304 can pass through to the front of the display apparatus 300. That is, the shutter 344 is placed in the OPEN position.

While not shown in FIG. 3, the display apparatus 300 can also include a pixel circuit associated with the shutter assembly 306 for providing electrical signals needed for actuating the first and the second set of actuators 346 and 348 appropriately based on a received data signal. In some implementations, the LTPS TFT 302 can be a part of the pixel circuit. One of skill in the art would appreciate that the display apparatus 300 shown in FIG. 3 is merely one illustrative example. The technique disclosed herein can be applicable to other display apparatus that may include more or fewer components than those shown in FIG. 3.

FIGS. 4A-4J show example cross-sectional views of the display apparatus 300 shown in FIG. 3, at various example stages of construction. FIG. 4A shows a stage of construction of the display apparatus 300 where the aperture layer 310 has been deposited and patterned over the substrate 308 to form the aperture 304. As mentioned above, the substrate 308 can be a transparent substrate and can be formed of materials such as, but not limited to, plastic or glass. In some implementations, the aperture layer 310 can be deposited as a thin film over the substrate 308. As mentioned above, the aperture layer 310 can be reflective on the side of the aperture layer 310 that faces the substrate 308. In some implementations, materials such as, but not limited to silver (Au), mercury (Ag), and aluminum (Al) can be used to form the aperture layer 310. In some implementations, the reflectance of the aperture layer 310 can be enhanced if the material used to form the aperture layer 310 is deposited in such a way so as to produce a dense and smooth thin film, as can be achieved via sputtering or by ion assisted evaporation. In some implementations, the aperture layer 310 can be formed by a plurality of layers with varying refractive indices in addition to the reflective metal layer to enhance the reflectance of the aperture layer 310. In some implementations, the aperture layer 310 can be patterned using a photomask followed by etching to form the aperture 304. While only a single aperture 304 is shown in FIGS. 3 and 4A-4J, it is understood that the aperture layer 304 can include a plurality of apertures associated with a plurality of pixel regions formed on the display apparatus 300.

The formation of the aperture layer can be followed by the deposition and patterning of a first insulation layer 312, as shown in FIG. 4B. The first insulation layer can be formed from a dielectric material such as, without limitation, silicon-di-oxide (SiO₂), silicon nitride (Si₃N₄), aluminum oxide (Al₂O₃), titanium oxide (TiO₂), hafnium oxide (HfO₂), tantalum pentoxide (Ta₂O₅), etc. In some implementations, deposition techniques such as, but not limited to, chemical vapor deposition (CVD), plasma enhanced chemical vapor deposition (PECVD), low pressure chemical vapor deposition (LPCVD), atomic or self-limited layer deposition (ALD), evaporation, etc., may be used to deposit the first insulation layer 312. The first insulation layer 312 is also patterned such that the opening in the first insulation layer 312 substantially coincides with the opening in the aperture layer 310 to maintain the aperture 304.

FIG. 4C shows the results of a stage of construction of the display apparatus 300 that is used for the formation of a polycrystalline silicon channel 314. As mentioned above, in some implementations, the polycrystalline silicon channel 314 can be formed by a laser annealing process applied to amorphous silicon. In some implementations, a layer of amorphous silicon can be deposited and then converted to polycrystalline silicon using excimer laser annealing before being patterned into the polycrystalline silicon channel 314.

The formation of the polycrystalline silicon channel 314 can be followed by the deposition and patterning of the second insulation layer 318, as shown in FIG. 4D. In some implementations, the second insulation layer 318 can be formed of materials similar to those employed for forming the first insulation layer 312. The second insulation layer 318 can be patterned such that second insulation layer 318 includes an opening that substantially coincides with the aperture 304 in the aperture layer 310.

In some implementations, the second insulation layer 318 can be patterned to include two additional openings that expose regions in the underlying polycrystalline silicon channel 314. These openings can be used to allow for the source and drain terminals of the LTPS TFT 302 to contact the channel 314. In some implementations, the thickness of the second dielectric layer 318 can be based on a desired thickness of the gate dielectric of the LTPS TFT 302. The thickness of the gate dielectric of the LTPS TFT 302 can affect several characteristics such as transconductance, capacitance, switching speed, etc., of the LTPS TFT 302.

FIG. 4E shows the results of a stage of construction of the display apparatus 300 in which a gate metal layer is deposited and patterned into a gate terminal 316 of the LTPS TFT 302. The gate terminal 316 can be formed from conductive materials such as, but not limited to, aluminum (Al), copper (Cu), silver (Ag), nickel (Ni), chromium (Cr), molybdenum (Mo), tungsten (W), titanium (Ti), etc. As the gate terminal 316 is deposited after the deposition of the polycrystalline silicon channel 314, the resulting LTPS TFT 302 can be referred to as a top-gate transistor. In some other implementations, the gate terminal 316 may be formed before the formation of the polycrystalline silicon channel 314. In such implementations, the LTPS TFT 302 may be referred to as a bottom-gate transistor. The display apparatus 300 can be manufactured with either TFT configuration (top-gate or bottom-gate).

In some implementations, the formation of the gate terminal 316 can be followed by the deposition and patterning of the third insulation layer 320, the results of which are shown in FIG. 4F. The third insulation layer 320 can be formed of materials similar to those employed in forming the first insulation layer 312. The third insulation layer 320 can be patterned to form an opening that coincides with the aperture 304 in the underlying aperture layer 310. The third insulation layer 320 can also be patterned such that it covers the gate terminal 316, and includes openings that expose the underlying polycrystalline silicon channel 314 through the second insulation layer 318. These openings can allow for the source and drain terminals to make electrical contact with the channel 314.

FIG. 4G shows a stage of construction of the display apparatus 300 in which a light absorbing metal layer is deposited and patterned to form the source and drain terminals 322 and 324 in addition to a light absorbing mask that includes a front facing light absorbing portion 326 and light absorbing sidewall coating portions 328 and 330 on the sidewalls of the aperture 304. The light absorbing material used to form the light absorbing mask can include any conductor that is also substantially light absorbing. For example, in some implementations, the light absorbing mask can be formed from a thin film of metal alloys, such as, but not limited to, molybdenum-chromium (MoCr), molybdenum-tungsten (MoW), molybdenum-titanium (MoTi), molybdenum-tantalum (MoTa), titanium-tungsten (TiW), titanium-chromium (TiCr), etc. Other metal alloys formed of nickel and chromium with rough surfaces that are effective at absorbing light can also be used for forming the light absorbing mask. In some implementations, the light absorbing material used for forming the light absorbing mask can be deposited by sputter deposition in high gas pressures (sputtering atmospheres in excess of 20 mtorr). Rough metals can also be formed by the liquid spray or plasma spray application of a dispersion of metal particles, followed by thermal sintering. The deposited light absorbing material can then be patterned to result in the front facing light absorbing portion 326 of the light absorbing mask, the source and drain terminals 322 and 324, and the sidewall coating portions 328 and 330, as shown in FIG. 4G.

In some implementations, the light absorbing mask (including the front facing light absorbing portion 326 and the sidewall coating portions 328 and 330) can be formed using more than one sub-layers. For example, in some implementations, one of the sub-layers can include a conductive material used for forming the source and drain terminals 322 and 324 of the LTPS TFT 302. In some such implementations, the conductive material can include any metals that are suitable for forming the source and drain terminals, such as, but not limited to Cr, Al, Cu, Ag, etc. Another one of the sub-layers, deposited over the conductive metal, can include a light absorbing material such as the light absorbing metal alloys or light absorbing rough metals discussed above. In some implementations, each of the sub-layers can be deposited and patterned separately from the other sub-layers used for forming the light absorbing mask. In some implementations, the source and drain terminals 322 and 324 also can be formed of the same sub-layers as the light absorbing mask.

FIG. 4H shows the results of a stage of construction of the display apparatus 300 in which the fourth insulation layer 332 has been deposited and patterned. The fourth insulation layer can be formed of materials similar to those employed in forming the first insulation layer 312. The fourth insulation layer 332 is patterned to form an opening that coincides with the aperture 304 in the aperture layer 310. The fourth insulation layer 332 is patterned to also include additional openings to allow vias to make contact with the source and drain terminals 322 and 324 and the front facing light absorbing portion 326 of the light absorbing mask.

Following the deposition and patterning of the fourth insulation layer 332, another conductive layer can deposited and patterned to form vias, the results of which are shown in FIG. 4I. As discussed above in relation to FIG. 3, the first via 334 makes contact with the source terminal 322, the second via 336 makes contact with the drain terminal 324, while the third via 338 makes contact with the front facing light absorbing coating 326. The first via 334 and the second via 336 can provide contacts to various interconnects to connect to the source and drain terminals 322 and 324 of the LTPS TFT 302. The third via 338 can allow the shutter assembly (to be fabricated in later stages of fabrication) to make electrical contact with the front facing light absorbing portion 326 of the light absorbing mask.

FIG. 4J shows the results of a stage of construction of the display apparatus 300 in which the fifth insulation layer 340 is deposited and patterned. The fifth insulation layer can be formed of materials similar to those used for forming the first insulation layer 312. The fifth insulation layer 340 can provide electrical and physical isolation to the underlying LTPS TFT 302 from forthcoming stages of construction of the display apparatus 300. The fifth insulation layer 340 is patterned such that a portion of the third via 338 is left exposed. This can allow the third via 338 to make electrical contact with the shutter assembly 306.

Following the deposition and patterning of the fifth insulation layer 340, the construction of the display apparatus 300 can include formation of the shutter assembly 306, a result of which is shown in FIG. 3. The construction of the shutter assembly can include the formation of a mold over which the shutter assembly is formed, followed by a patterning stage, and a release stage. To form the mold, a first sacrificial material is deposited and patterned to form vias or openings in which a portion of the anchor 342 can be formed. A second sacrificial material is deposited on top of the patterned first layer of sacrificial material. The second layer of sacrificial material is patterned to form a mold, which includes substantially vertical sidewalls and a top surface. The mold also includes vias or openings that align with the vias and openings formed in the first sacrificial layer. The fabrication of the shutter assembly further includes deposition and patterning of a shutter material. The shutter material is deposited over the sidewalls and the top surface of the mold, and also in the openings or vias. The deposited shutter material is then patterned, typically, using anisotropic etching. The patterning is carried out in a manner such that the shutter material remains on the sidewalls of the mold to form the first and second set of actuator beams 348, on the upper surface of the mold to form the shutter 344, and in the openings of the mold to form the anchor 342. While the above discusses one example process for forming the shutter assembly 306, a person having ordinary skill in the art will readily understand that the shutter assembly 306 could be formed using other fabrication techniques.

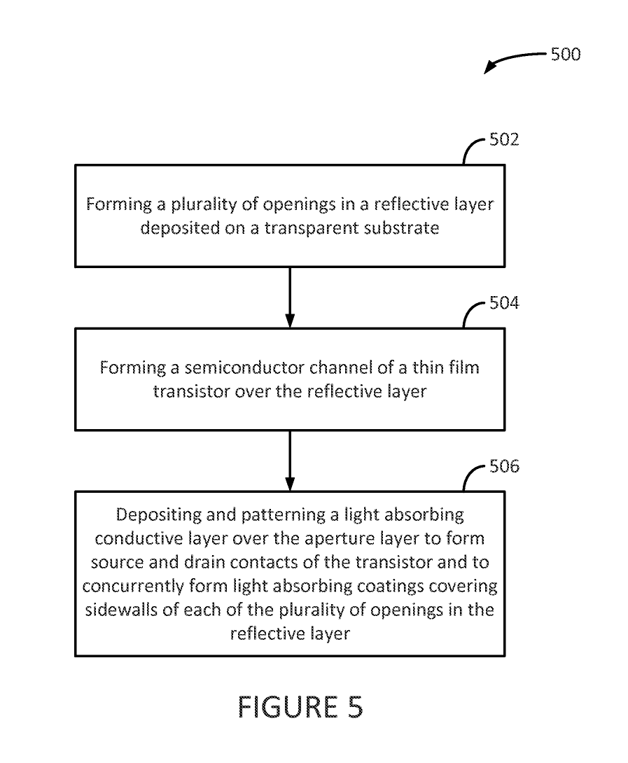

FIG. 5 shows a flow diagram of an example process 500 for forming a display apparatus. In particular, the process 500 includes the stages of manufacture for forming light absorbing coatings over various portions of the display apparatus. In some implementations, the process 500 can be used, in part, to manufacture the display apparatus 300 shown in FIG. 3. The process 500 includes forming a plurality of openings in a reflective layer deposited on a transparent substrate (stage 502), forming a semiconductor channel of a thin film transistor over the reflective layer (stage 504), and depositing and patterning a light absorbing conductive layer over the aperture layer to form source and drain contacts of the transistor and to concurrently form light absorbing coatings covering sidewalls of each of the plurality of openings in the reflective layer (stage 506).

The process 500 includes forming a plurality of openings in a reflective layer deposited on a transparent substrate (stage 502). Examples of this process stage have been discussed above in relation to FIGS. 3 and 4A. As shown in FIGS. 3 and 4A, the opening 304 is formed in the aperture layer 310 deposited over the transparent substrate 308. As discussed above, a plurality of apertures such as aperture 304 can be formed in the aperture layer 310.

The process 500 also includes forming a semiconductor channel of a thin film transistor over the reflective layer (stage 504). One example of this process stage has been discussed above in relation to FIG. 4C. As shown in FIG. 4C, a polycrystalline silicon channel 314 is formed over the first insulation layer 312, which, in turn, is formed over the aperture layer 310. As discussed above, in some implementations, the polycrystalline silicon channel 314 can be formed by first depositing a layer of amorphous silicon, and then carrying out an annealing process to convert the amorphous silicon into polycrystalline silicon. The converted polycrystalline silicon can then be patterned to form the polycrystalline silicon channel 314.

The process 500 further includes depositing and patterning a light absorbing conductive layer over the aperture layer to form source and drain terminals of the transistor and to concurrently form light absorbing coatings covering sidewalls of each of the plurality of openings in the reflective layer (stage 506). One example of this process stage has been discussed above in relation to FIG. 4G. As shown in FIG. 4G, a light absorbing metal layer is deposited and patterned to form source and drain terminals 322 and 324 and a light absorbing mask that includes the front facing light absorbing portion 326, and the light absorbing sidewall coating portions 328 and 330. As discussed above, the front facing light absorbing portion 326 absorbs light incident on its front facing surface form the front of the display apparatus 300. The light absorbing sidewall coating portions 328 and 330 absorb light impinging on the sidewalls of the aperture 304 that would otherwise reflect off the sidewalls as it passes through the aperture 304. The absorption of light by the front facing light absorbing portion 326 and the sidewall coating portions 328 and 330 of the light absorbing mask can contribute to improving the contrast ratio of the display apparatus 300.

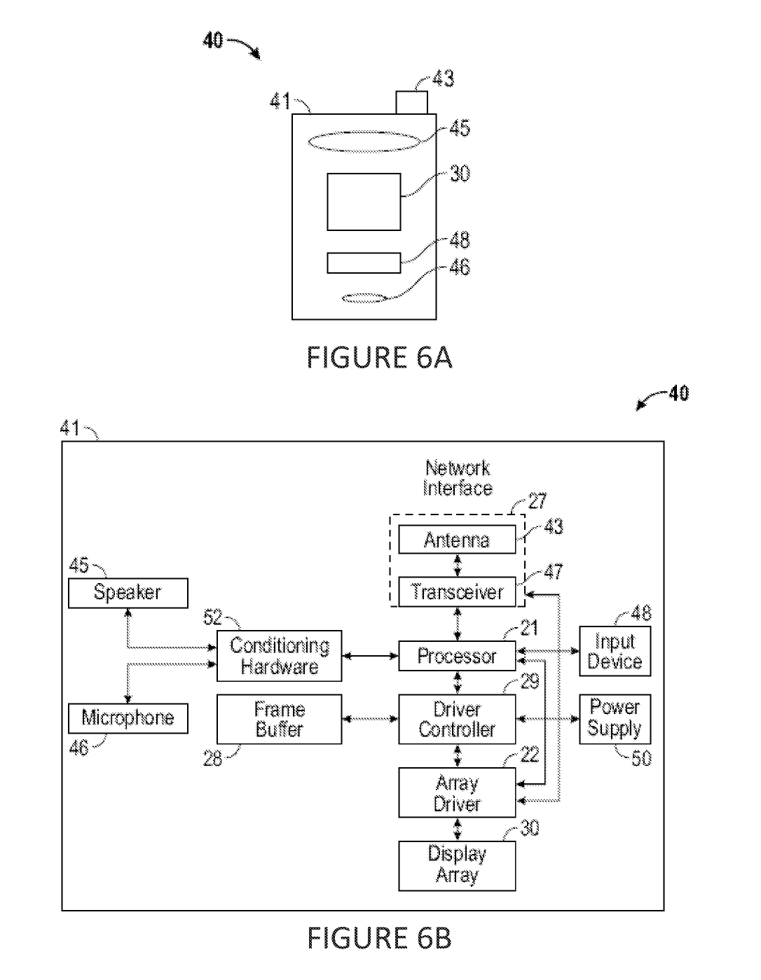

FIGS. 6A and 6B show system block diagrams of an example display device 40 that includes a plurality of display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, electroluminescent (EL) displays, OLED, super twisted nematic (STN) display, LCD, or thin-film transistor (TFT) LCD, or a non-flat-panel display, such as a cathode ray tube (CRT) or other tube device. In addition, the display 30 can include a mechanical light modulator-based display, as described herein.

The components of the display device 40 are schematically illustrated in FIG. 6A. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIGS. 6A and 6B, can be configured to function as a memory device and be configured to communicate with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, ac, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements. In some implementations, the array driver 22 and the display array 30 are a part of a display module. In some implementations, the driver controller 29, the array driver 22, and the display array 30 are a part of the display module.

In some implementations, the driver controller 29, the array driver 22, and the display array 30 are appropriate for any of the types of displays described herein. For example, the driver controller 29 can be a conventional display controller or a bi-stable display controller (such as a mechanical light modulator display element controller). Additionally, the array driver 22 can be a conventional driver or a bi-stable display driver (such as a mechanical light modulator display element controller). Moreover, the display array 30 can be a conventional display array or a bi-stable display array (such as a display including an array of mechanical light modulator display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus, comprising:
a transparent substrate;
an aperture layer having a plurality of apertures, each of the plurality of apertures having a light absorbing conductive coating covering their respective sidewalls of each of the plurality of apertures; and
a thin film transistor disposed over the aperture layer, the transistor having a semiconductor channel disposed over the aperture layer, a source metal contact, and a drain metal contact, the source and drain metal contacts being formed concurrently with, and of the same material as, the light absorbing conductive coating formed on the sidewalls of each of the plurality of apertures.

2. The apparatus of claim 1, wherein the semiconductor channel includes polycrystalline silicon.

3. The apparatus of claim 1, further comprising an additional light absorbing material covering the light absorbing conductive coating formed on the sidewalls and covering the source and drain metal contacts.

4. The apparatus of claim 1, further including a front facing light absorbing conductive coating over the aperture layer formed concurrently with the light absorbing conductive coating formed on the sidewalls of each of the plurality of apertures.

5. The apparatus of claim 4, further including a shutter assembly having a shutter supported by an anchor, the anchor electrically connected to the front facing light absorbing conductive coating.

6. The apparatus of claim 1, wherein the transistor further includes a gate terminal, the gate terminal disposed between the semiconductor channel and the aperture layer.

7. The apparatus of claim 1, wherein the transistor further includes a gate terminal, the semiconductor channel being disposed between the gate terminal and the aperture layer.

8. The apparatus of claim 1, further comprising:
a display including the substrate, the aperture layer and the transistor,
a processor that is capable of communicating with the display, the processor being capable of processing image data; and
a memory device that is capable of communicating with the processor.

9. The apparatus of claim 8, the display further including:
a driver circuit capable of sending at least one signal to the display; and
a controller capable of sending at least a portion of the image data to the driver circuit.

10. The apparatus of claim 8, further including:
an image source module capable of sending the image data to the processor, wherein the image source module comprises at least one of a receiver, transceiver, and transmitter.

11. The apparatus of claim 8, the display device further including:
an input device capable of receiving input data and to communicate the input data to the processor.

12. A method for forming a display apparatus, comprising:
forming a plurality of openings in a reflective layer deposited on a transparent substrate;
forming a semiconductor channel of a thin film transistor over the reflective layer; and
depositing and patterning a light absorbing conductive layer to form source and drain contacts of the transistor and to concurrently form light absorbing coatings covering sidewalls of each of the plurality of openings.

13. The method of claim 12, further comprising depositing and patterning an additional light absorbing material to cover the source and drain contacts and to cover the light absorbing coatings covering the sidewalls of each of the plurality of openings.

14. The method of claim 12, wherein forming the semiconductor channel of the transistor over the reflective layer includes converting an amorphous silicon material deposited over the aperture layer into polycrystalline silicon by an annealing process.

15. The method of claim 12, further comprising forming a gate terminal of the transistor prior to forming the semiconductor channel of the transistor over the reflective layer.

16. The method of claim 12, further comprising forming a gate terminal of the transistor after forming the semiconductor channel of the transistor over the reflective layer.

17. The method of claim 12, wherein depositing and patterning the light absorbing conductive layer to form source and drain contacts of the transistor and to concurrently form light absorbing coatings covering the sidewalls of each of the plurality of openings further includes patterning a front facing light absorbing conductive coating over the aperture layer.

18. The method of claim 17, further comprising forming a shutter assembly over the aperture layer such that at least a portion of the shutter assembly is in electrical contact with the front facing light absorbing conductive coating.
